(19) United States
(12) Patent Application Publication
(10) Pub. No.: US 2025/0263640 A1
(43) Pub. Date: Aug. 21, 2025

(54) RINSE COMPOSITION AND METHOD FOR MANUFACTURING DEVICE USING THE SAME

(71) Applicant: DONGWOO FINE-CHEM CO., LTD., Iksan-si (KR)

(72) Inventors: Yong-Hwan CHO, Iksan-si (KR); So-Min LEE, Iksan-si (KR); Ji-Min CHUN, Iksan-si (KR)

(73) Assignee: DONGWOO FINE-CHEM CO., LTD., Iksan-si (KR)

(21) Appl. No.: 19/057,471

(22) Filed: Feb. 19, 2025

(30) Foreign Application Priority Data
Feb. 20, 2024 (KR) 10-2024-0024609

(51) Int. Cl. C11D 7/50; C11D 7/26; G03F 7/40

(52) U.S. Cl. CPC C11D 7/5022; C11D 7/263; G03F 7/40

(57) ABSTRACT

The present disclosure provides a rinse composition including a glyceryl ether compound represented by Chemical Formula 1, and a method for manufacturing a device using the same.

### CROSS-REFERENCE TO RELATED APPLICATION(S)

This application claims the benefit under 35 USC 119(a) of Korean Patent Application No. KR 10-2024-0024609, filed on Feb. 20, 2024, with the Korean Intellectual Property Office, the disclosure of which is incorporated herein by reference in its entirety.

### TECHNICAL FIELD

The present disclosure provides a rinse composition including a glyceryl ether compound represented by Chemical Formula 1, and a method for manufacturing a device using the same.

### BACKGROUND ART

As an aspect ratio of a pattern increases in a photolithography process used for forming a fine structure in a semiconductor process, a pattern collapse occurs in a drying process by capillary force of water droplets pulling a micropattern when an exposed portion is developed in a developing process using a developing solution and then washed generally with deionized water and dried. In order to resolve such a problem, a method of reducing pattern defects, which occur during washing and drying processes, through a rinsing step having lower surface tension is used after treating with a developing solution.

In addition, an effect of improving an overall process margin of a photolithography process by increasing resolution of a micropattern formed by removing development residue not completely removed by a developing solution in a rinsing step after development has also been reported, and a composition used in the rinsing step is required to have a proper cleaning power so as to remove the residue on the bottom surface of a photoresist pattern. However, approaching from this perspective causes a problem of dissolving a photoresist pattern formed with organic compounds, especially polymer compounds, and deforming the pattern itself, and therefore, it is important that a rinse composition does not cause damage to a photoresist pattern.

Japanese Patent Application Laid-Open No. 2023-147904 provides a cleanser composition for textile products. However, such a composition not only causes damage to a photoresist pattern, but also has a problem of causing a pattern collapse when performing a rinse process for a micropattern, and therefore, a solution for such problems has been required.

### PRIOR ART DOCUMENTS

### Patent Documents

(Patent Document 1] Japanese Patent Application Laid-Open No. 2023-147904

### DISCLOSURE

### Technical Problem

The present disclosure has been made in view of the above, and is directed to providing a rinse composition capable of, in a rinse process for a photoresist pattern of a micropattern, obtaining excellent rinse performance and minimizing damage to the photoresist pattern while preventing a collapse of the micropattern.

The present disclosure is directed to providing a method for manufacturing a device using the rinse composition.

### Technical Solution

One embodiment of the present disclosure provides a rinse composition including a glyceryl ether compound represented by Chemical Formula 1.

One embodiment of the present disclosure provides a method for manufacturing a device using the rinse composition.

### Advantageous Effects

A rinse composition according to the present disclosure is, in a rinse process for a photoresist pattern of a micropattern, capable of obtaining excellent rinse performance and minimizing damage to the photoresist pattern while preventing a collapse of the micropattern.

### BRIEF DESCRIPTION OF DRAWINGS

FIG. 1 schematically illustrates a method for manufacturing a device of the present disclosure.

FIG. 2A shows an evaluation area for a pattern collapse test of the present disclosure, FIG. 2B shows a result of observing a photoresist pattern collapse after rinsing with a rinse composition of Example 1 of the present disclosure, and FIGS. 2C and 2D show results of a photoresist pattern collapse after rinsing with rinse compositions of Comparative Examples 1 and 2, respectively.

FIG. 3A shows a result of observing damage to a photoresist pattern after rinsing with the rinse composition of Example 1 of the present disclosure, and FIG. 3B shows a result of observing damage to a photoresist pattern after rinsing with the rinse composition of Comparative Example 1.

### BEST MODE

The present disclosure relates to a rinse composition including a glyceryl ether compound represented by Chemical Formula 1, and a method for manufacturing a device using the same.

The rinse composition according to the present disclosure may be for rinsing a photoresist pattern prepared by exposing and then developing a photoresist film. Particularly, when used in a rinse process for a micropattern, the rinse composition of the present disclosure does not damage the pattern while preventing a collapse of the pattern. The photoresist pattern of the present disclosure may have a line width of 250 nm or less.

### <Rinse Composition>

The rinse composition of the present disclosure includes a glyceryl ether compound represented by Chemical Formula 1.

### (a) Glyceryl Ether Compound Represented by Chemical Formula 1

In the present disclosure, a glyceryl ether compound represented by Chemical Formula 1 is included so as not to adversely affect a photoresist pattern while preventing a collapse of a micropattern having a high aspect ratio.

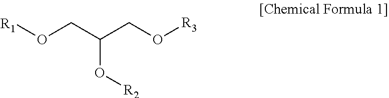

In Chemical Formula 1,
R₁ is a linear, branched or cyclic alkyl group having 1 to 12 carbon atoms, and
R₂ and R₃ each independently represent a linear, branched or cyclic alkyl group having 1 to 4 carbon atoms, or hydrogen,
however, all of R₁, R₂ and R₃ are not a methyl group.

Preferably, in Chemical Formula 1, R₁ is a linear, branched or cyclic alkyl group having 3 to 12 carbon atoms, and
R₂ and R₃ each independently represent a linear, branched or cyclic alkyl group having 1 to 4 carbon atoms, or hydrogen,
however, all of R₁, R₂ and R₅ are not a methyl group, and both R₂ and R₃ are not hydrogen.

In one embodiment, the glyceryl ether compound represented by Chemical Formula 1 may include one or more types of compounds selected from among compounds represented by the following Chemical Formulae 1-1 to 1-6.

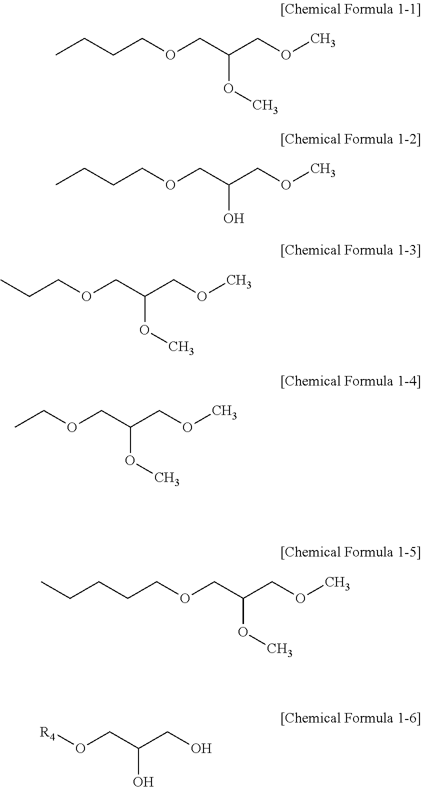

In Chemical Formula 1-6,
R₄ represents a linear or branched alkyl group having 4 to 8 carbon atoms.

The glyceryl ether compound represented by Chemical Formula 1 has a structure having a hydrophilic head and a hydrophobic tail in a solvent molecule, and acts on a liquid interface to lower surface tension, and the lowered surface tension reduces capillary force that pulls and collapses a pattern. Accordingly, even when the photoresist pattern is a micropattern, an excellent pattern collapse prevention effect is obtained in a rinse process.

The glyceryl ether compound of the present disclosure may be added to an aqueous solution to form a rinse solution composition, and may contribute to the improvement in overall process yield by reducing the phenomenon of pattern collapse during the developing and rinsing processes of a photoresist.

The glyceryl ether compound represented by Chemical Formula 1 may be included in an amount of 0.1% by weight to 13% by weight, preferably 0.5% by weight to 10% by weight and more preferably 0.5% by weight to 5% by weight with respect to the total weight of the rinse composition, and most preferably, adding in an amount of 1% by weight to 5% by weight is effective. When included in an amount of less than the above-mentioned range, it is difficult to expect the effect of preventing a pattern collapse, and being included in an amount of greater than the above-mentioned range is not preferred since the photoresist pattern may be dissolved, causing damage to the pattern.

### (b) Water-Soluble Organic Solvent

The present disclosure may further include a water-soluble organic solvent as an additional component. The water-soluble organic solvent may be one or more types of alcohol, ketone, and ether compounds other than Chemical Formula 1, and in this case, the surface tension is lowered by a complementary action, more effectively suppressing a pattern collapse compared to when using the glyceryl ether compound represented by Chemical Formula 1 alone, and an improvement in the cleaning effect for the development residue between patterns may also be expected. More specifically, the water-soluble organic solvent may include one or more types of isopropyl alcohol, 2-butanone, tert-butyl methyl ether, di-alkyl-ethylene glycol ether and di-alkyl-diethylene glycol ether.

The water-soluble organic solvent is preferably included in an amount of 5% by weight to 25% by weight with respect to the total weight of the rinse composition in terms of a proper complementary action.

In addition, in order to further improve the effects, the rinse composition of the present disclosure may further include common additives in addition to the components described above.

The rinse composition of the present disclosure may include a solvent, and the solvent may be included in a residual amount with respect to the (a) component, or (a) component and (b) component, or other additional additives. The solvent may be water.

The rinse composition of the present disclosure may not include an acid compound and an alkaline compound in order to minimize damage to the photoresist. The acid or alkaline compound may dissolve the pattern formed with polymer components, causing deformation the pattern shape and delamination of the pattern.

### <Method for Manufacturing Device>

The present disclosure includes a method for manufacturing a device using the rinse composition described above, and a device manufactured thereby as the scope of the disclosure.

The method for manufacturing a device and the device of the present disclosure are not particularly limited as long as the rinse composition of the present disclosure described above is used.

For example, the method for manufacturing a device of the present disclosure may include rinsing a photoresist pattern with the rinse composition of the present disclosure.

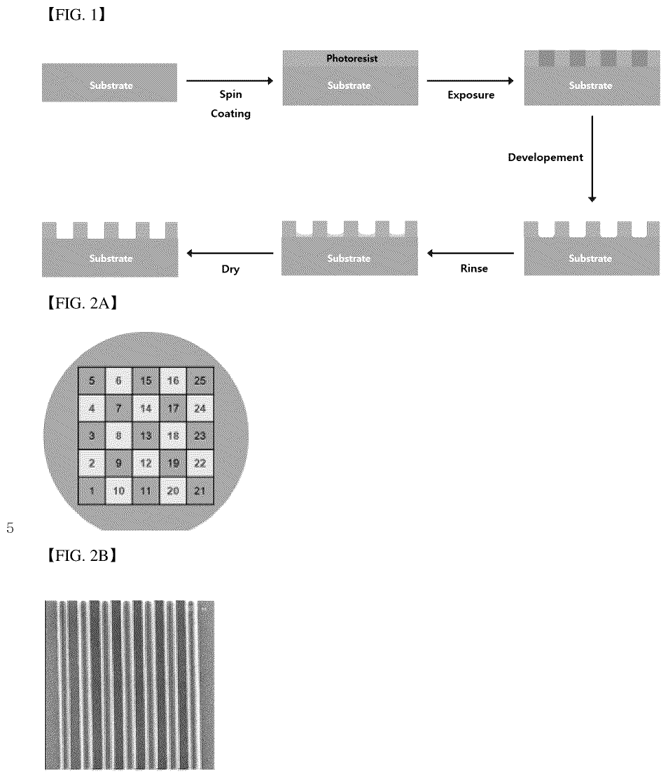

FIG. 1 schematically illustrates the method for manufacturing a device of the present disclosure.

More specifically, referring to FIG. 1, the method for manufacturing a device of the present disclosure includes: forming a photoresist film on a substrate; exposing the photoresist film; forming a photoresist pattern by developing the exposed photoresist film; and rinsing the photoresist pattern using the rinse composition described above. In addition, the method may further include drying the rinsed photoresist pattern.

Hereinafter, the present disclosure will be described in more detail with reference to examples. However, the following examples are intended to more specifically describe the present disclosure, and the scope of the present disclosure is not limited by the following examples.

### EXAMPLE AND COMPARATIVE EXAMPLE

### Examples 1 to 14 and Comparative Examples 1 to 6: Preparation of Rinse Composition

Components presented in the following Table 1 were mixed according to their respective contents to prepare rinse compositions of Examples 1 to 14 and Comparative Examples 1 to 6.

TABLE 1

| Classifi- | | Example | | | | | | | | | | |
|---|---|---|---|---|---|---|---|---|---|---|---|---|
| cation | | 1 | 2 | 3 | 4 | 5 | 6 | 7 | 8 | 9 | 10 | 11 |
| Com- | A-1 | 13.0 | 10.0 | 5.0 | 1.0 | 0.5 | 0.1 | — | — | — | — | — |
| pound | A-2 | — | — | — | — | — | — | 5.0 | — | — | — | — |
| (A) | A-3 | — | — | — | — | — | — | — | 5.0 | — | — | — |
| | A-4 | — | — | — | — | — | — | — | — | 5.0 | — | — |
| | A-5 | — | — | — | — | — | — | — | — | — | 5.0 | — |
| | A-6 | — | — | — | — | — | — | — | — | — | — | 5.0 |
| | A-7 | — | — | — | — | — | — | — | — | — | — | — |
| | A-8 | — | — | — | — | — | — | — | — | — | — | — |
| | A-9 | — | — | — | — | — | — | — | — | — | — | — |
| | A-10 | — | — | — | — | — | — | — | — | — | — | — |
| | S-1 | — | — | — | — | — | — | — | — | — | — | — |
| Solvent | S-2 | — | — | — | — | — | — | — | — | — | — | — |
| (S) | S-3 | — | — | — | — | — | — | — | — | — | — | — |

| | | | | | | | | | | | |
|---|---|---|---|---|---|---|---|---|---|---|---|
| DIW | 87.0 | 90.0 | 95.0 | 99.0 | 99.5 | 99.9 | 95.0 | 95.0 | 95.0 | 95.0 | 95.0 |

| Classifi- | | Example | | | Comparative Example | | | | | |
|---|---|---|---|---|---|---|---|---|---|---|
| cation | | 12 | 13 | 14 | 1 | 2 | 3 | 4 | 5 | 6 |
| Com- | A-1 | 5.0 | 5.0 | 5.0 | — | — | — | — | — | — |
| pound | A-2 | — | — | — | — | — | — | — | — | — |
| (A) | A-3 | — | — | — | — | — | — | — | — | — |
| | A-4 | — | — | — | — | — | — | — | — | — |
| | A-5 | — | — | — | — | — | — | — | — | — |
| | A-6 | — | — | — | — | — | — | — | — | — |
| | A-7 | — | — | — | 5.0 | — | — | — | — | — |
| | A-8 | — | — | — | — | 5.0 | — | — | — | — |
| | A-9 | — | — | — | — | — | 5.0 | — | — | — |
| | A-10 | — | — | — | — | — | — | 5.0 | — | — |
| | S-1 | 10.0 | — | — | — | — | — | — | 10.0 | — |
| Solvent | S-2 | — | 10.0 | — | — | — | — | — | — | — |
| (S) | S-3 | — | — | 10.0 | — | — | — | — | — | — |

| | | | | | | | | | |
|---|---|---|---|---|---|---|---|---|---|
| DIW | 85.0 | 85.0 | 85.0 | 95.0 | 95.0 | 95.0 | 95.0 | 90.0 | 100.0 |

S-1: Isopropyl alcohol
S-2: 2-Butanone

S-3: Tert-butyl methyl ether
A-1 to A-10: As shown below

| Code | Chemical Name | Structure |
|---|---|---|
| A-1 | 2,3-Dimethoxypropanol n-butyl ether | 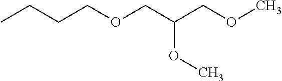 |
| A-2 | 2-Hydroxy-3-methoxypropanol n-butyl ether | 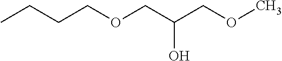 |
| A-3 | 2,3-Dimethoxypropanol n-propyl ether | 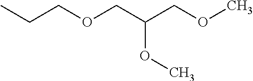 |
| A-4 | 2,3-Dimethoxypropanol ethyl ether | 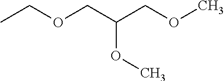 |
| A-5 | 2,3-Dimethoxypropanol n-pentyl ether | 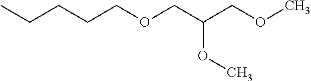 |
| A-6 | Glycerol mono-butyl ether | 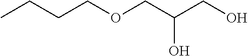 |
| A-7 | 2-Butoxyethanol | 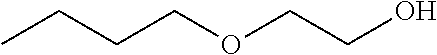 |
| A-8 | n-Butanol | 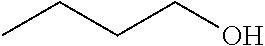 |
| A-9 | 1,2,3-Trimethoxypropane | 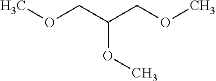 |
| A-10 | Glycerol | 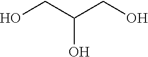 |

### Experimental Example

### 1. Preparation of Photoresist Composition

### (1) Synthesis of Binder Polymer (1)

A binder polymer (1) was synthesized according to the following Reaction Formula 1. Specifically, a flask substituted with nitrogen was filled with tetrahydofuran (THF) (750 mL), and after dissolving styrene (16.0 g, 0.15 mol) and 4-acetoxystyrene (120.4 g, 0.74 mol) therein, the temperature was lowered to −60° C. After that, the mixture was stirred while slowly adding n-butyllithium (10.2 mL, 25.6 mmol/2.5 M n-hexane solution) dropwise thereto over one hour to perform a polymerization reaction. Immediately thereafter, t-butyl methacrylate (54.6 g, 0.38 mol) was slowly added dropwise thereto over one hour, and then the mixture was further stirred for one hour while maintaining the temperature at −60° C. After identifying the completion of the reaction using gas chromatography (GC), methanol (100 mL) was slowly added dropwise thereto to terminate the reaction, and, by additionally introducing methanol (800 mL) to the reaction mixture, the polymerized polymer compound was precipitated. The precipitates were filtered, washed several times with methanol, dried, and then dissolved in tetrahydofuran (THF) (500 mL) and methanol (100 mL) again. After introducing sodium methoxide (5.0 g, 0.09 mol) thereto, the temperature was raised to 65° C., and the mixture was stirred for 5 hours. After identifying that the acetoxystyrene included as a functional group was converted to hydroxystyrene by FT-IR (peak 1765 cm-1), the reaction solution was cooled to room temperature, and after introducing a large amount of deionized water thereto to precipitate the polymer compound, the precipitates were washed, and dried using a vacuum oven. Finally, a binder polymer (1) (139.0 g, 87% yield) having a weight average molecular weight measured by GPC of 8,750 and dispersity of 1.12 was able to be obtained.

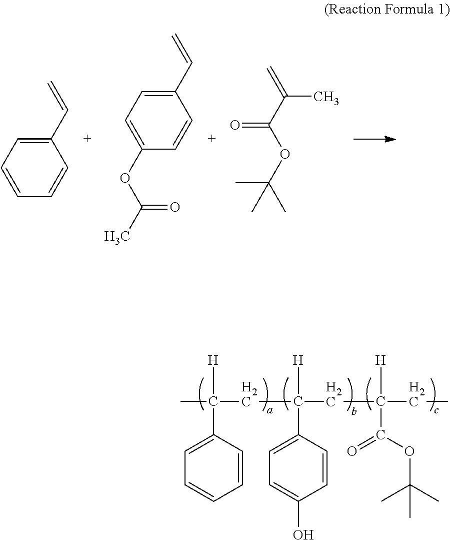

### (2) Preparation of Photoresist Composition

To a brown glass container, propylene glycol methyl ether acetate (PGMEA) (50 g) and 3-ethoxypropionic acid ethyl ester (EEP) (40 g) were introduced, and after adding the binder polymer (1) (14.5 g) synthesized above, triphenylsulfonium trifluoromethanesulfonate (0.55 g) and N,N-dicyclohexylmethylamine (0.03 g) thereto, the mixture was stirred for 4 hours at room temperature. The photoresist solution was filtered through a 0.1 μm filter (material: PTFE), and then used for manufacturing a pattern through a lithography process.

### 2. Manufacture of Photoresist Pattern

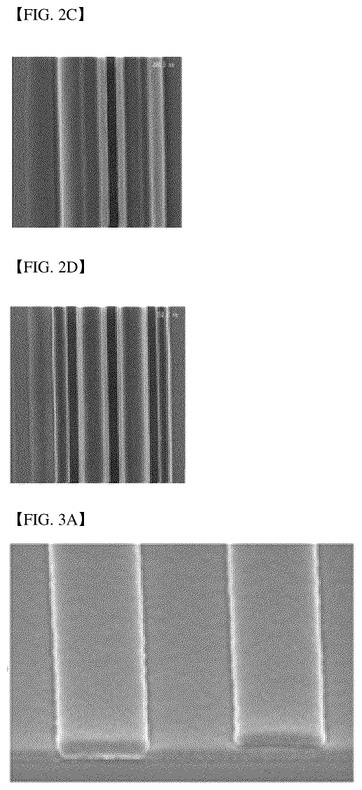

The photoresist solution (1.5 mL) was spin coated on a 6-inch silicon wafer and heated for 60 seconds at 110° C., and the solvent remaining on the film was removed to form a film to a thickness of 980 Å. The obtained photoresist film was exposed at 100 mJ/cm2 using a KrF light source (2=248 nm, Nikon NSR-S203B), and then post-exposure baked for 60 seconds at 110° C. After that, the exposed pattern was developed using a 2.38% aqueous tetramethylammonium hydroxide (TMAH) solution, then rinsed using the rinse composition, and the obtained pattern was observed using a CD-SEM (manufactured by Hitachi, Ltd.) to observe a pattern collapse. The obtained pattern was manufactured using a mask having a line-and-space pattern (1/1) with a line width of 200 nm, and a photoresist pattern for evaluation was manufactured by forming 25 identical pattern groups on a 6-inch wafer as shown in FIG. 2A.

### 3. Pattern Collapse Test

A photoresist pattern collapse test depending on the rinse compositions of the Examples and the Comparative Examples was performed by the evaluation area shown in FIG. 2A. Specifically, the pattern obtained through the rinsing for 20 seconds at 23° C. using each of the compositions of the Examples and the Comparative Examples after the exposure and the development was observed using a CD-SEM, and from the line-and-space pattern groups identically formed on a 6-inch wafer, 12 areas marked in FIG. 2A were selected and observed. The case in which a pattern collapse occurred in one area or less was determined as very good, the case in which a pattern collapse occurred in one to two areas was determined as good, the case in which a pattern collapse occurred in three or more areas was determined as average, and the case in which a pattern collapse occurred in five or more areas was determined as a pattern collapse being not properly suppressed. The experiment was repeated three times, and the results are shown in Table 2, and FIG. 2B to 2D. More specifically, FIG. 2B shows the result observed after rinsing with the rinse composition of Example 1 using a CD-SEM (manufactured by Hitachi, Ltd.), and it may be identified that a pattern collapse was not observed. FIGS. 2C and 2D show the results observed after rinsing with the rinse compositions of Comparative Example 1 and Comparative Example 2, respectively, using a CD-SEM (manufactured by Hitachi, Ltd.), and a pattern collapse was identified.

### 4. Pattern Damage Test

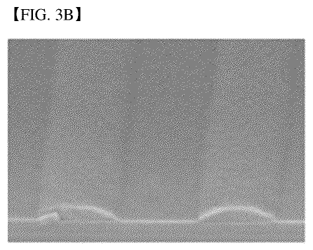

The pattern substrate manufactured through photolithography was dipped in each of the rinse compositions for 20 seconds at room temperature, and then dried. The surface state of the pattern was observed using a scanning electron microscope (SEM) (Regulus 8230, manufactured by Hitachi, Ltd.). When there was no change in the pattern, it was marked as O, and when the pattern was dissolved or deformed, it was marked as X. The results are shown in Table 2, and FIGS. 3A and 3B. More specifically, FIG. 3A shows the result observed after rinsing with the rinse composition of Example 1 using a scanning electron microscope (SEM), and it may be identified that pattern damage was not observed. FIG. 3B shows the result observed after rinsing with the rinse composition of Comparative Example 1 using an SEM, and pattern damage was identified.

TABLE 2

| Classifi- | Example | | | | | | | | | | |
|---|---|---|---|---|---|---|---|---|---|---|---|
| cation | 1 | 2 | 3 | 4 | 5 | 6 | 7 | 8 | 9 | 10 | 11 |
| Pattern | Level | Level | Level | Level | Level | Level | Level | Level | Level | Level | Level |
| Collapse | 4 | 4 | 1 | 2 | 3 | 5 | 1 | 2 | 3 | 1 | 3 |
| Photo | X | ◯ | ◯ | ◯ | ◯ | ◯ | ◯ | ◯ | ◯ | ◯ | ◯ |
| resist | | | | | | | | | | | |
| Damage | | | | | | | | | | | |

| Classifi- | Example | | | Comparative Example | | | | | |
|---|---|---|---|---|---|---|---|---|---|
| cation | 12 | 13 | 14 | 1 | 2 | 3 | 4 | 5 | 6 |
| Pattern | Level | Level | Level | Level | Level | Level | Level | Level | Level |
| Collapse | 1 | 1 | 1 | 6 | 8 | 7 | 10 | 8 | 10 |
| | or | or | or | | | | | | or |
| | lower | lower | lower | | | | | | higher |
| Photo | ◯ | ◯ | ◯ | X | X | ◯ | ◯ | ◯ | ◯ |
| resist | | | | | | | | | |
| Damage | | | | | | | | | |

Referring to the above-described experimental results, it may be identified that, in the photoresist pattern rinsed with the rinse composition of the Example of the present disclosure, pattern collapse or damage was prevented after rinsing even when forming a micropattern, and particularly, the rinse compositions of Examples 12 to 14 further including a water-soluble organic solvent exhibited a more superior pattern collapse prevention effect.

1. A rinse composition comprising a glyceryl ether compound represented by the following Chemical Formula 1: 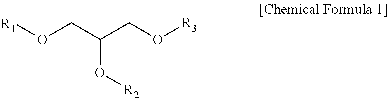
wherein, in Chemical Formula 1,
R₁ is a linear, branched or cyclic alkyl group having 1 to 12 carbon atoms; and
R₂ and R₃ each independently represent a linear, branched or cyclic alkyl group having 1 to 4 carbon atoms, or hydrogen;
however, all of R₁, R₂ and R₃ are not a methyl group.

2. The rinse composition of claim 1, wherein the glyceryl ether compound represented by Chemical Formula 1 includes one or more types of compounds selected from among compounds represented by the following Chemical Formulae 1-1 to 1-6. 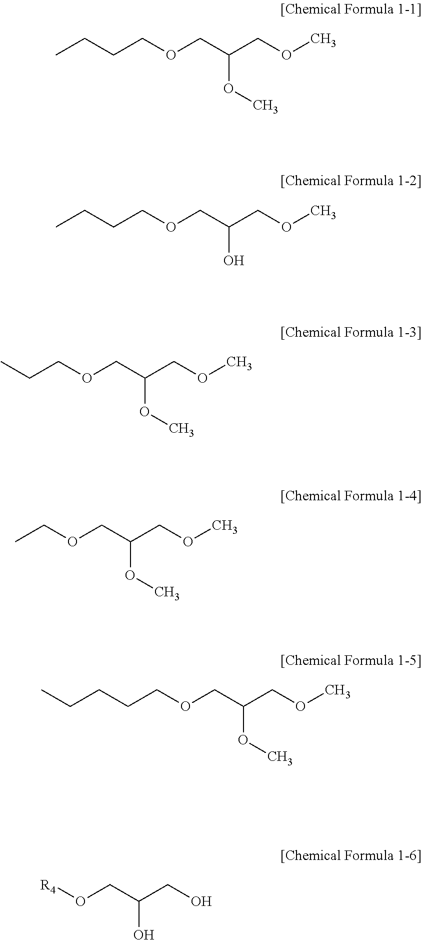
in Chemical Formula 1-6,
R₄ represents a linear or branched alkyl group having 4 to 8 carbon atoms.

3. The rinse composition of claim 1, wherein the glyceryl ether compound represented by Chemical Formula 1 is included in an amount of 0.1% by weight to 13% by weight with respect to a total weight of the rinse composition.

4. The rinse composition of claim 1, further comprising a water-soluble organic solvent.

5. The rinse composition of claim 4, wherein the water-soluble organic solvent includes one or more types of alcohol, ketone, and ether compounds other than Chemical Formula 1.

6. The rinse composition of claim 4, wherein the water-soluble organic solvent is included in an amount of 5% by weight to 25% by weight with respect to a total weight of the rinse composition.

7. The rinse composition of claim 1, which does not include an alkaline compound and an acid compound.

8. The rinse composition of claim 1, which is for rinsing a photoresist pattern prepared by exposing and then developing a photoresist film.

9. The rinse composition of claim 8, wherein the photoresist pattern has a line width of 250 nm or less.

10. The rinse composition of claim 8, which is for preventing the photoresist pattern from collapsing during the rinsing.

11. A method for manufacturing a device, the method comprising:
forming a photoresist film on a substrate;
exposing the photoresist film;
forming a photoresist pattern by developing the exposed photoresist film; and
rinsing the photoresist pattern using the rinse composition of claim 1.
